(19) United States
(12) Patent Application Publication
(10) Pub. No.: US 2026/0314099 A1
(43) Pub. Date: Oct. 8, 2026

(54) LIGHT DETECTION DEVICE AND ELECTRONIC APPARATUS

(71) Applicant: SONY SEMICONDUCTOR SOLUTIONS CORPORATION, KANAGAWA (JP)

(72) Inventor: KENTARO IMAMIZU, KUMAMOTO (JP)

(21) Appl. No.: 19/479,540

(22) PCT Filed: Apr. 18, 2024
(86) PCT No.: PCT/JP2024/015461

§ 371 Date: Oct. 28, 2025

(30) Foreign Application Priority Data
May 12, 2023 (JP) 2023-079298

(51) Int. Cl. H10F 39/00

(52) U.S. Cl. CPC H10F 39/807

(57) ABSTRACT

Provided is a light detection device capable of suppressing degradation of signal charge transfer characteristics. The light detection device includes: a semiconductor layer with one surface serving as an element formation surface and the other surface serving as a light incident surface, the semiconductor layer having a plurality of cell regions arranged in a matrix along row and column directions as viewed from above; a photoelectric conversion unit configured in each of the cell regions; and a trench isolation structure that extends along a thickness direction of the semiconductor layer and serves as a partition between the cell regions, the trench isolation structure includes a conductive wall including a conductive material, and an isolation insulating film that is provided on a side surface of the conductive wall and insulates the conductive wall from the semiconductor layer, and a film thickness of a portion of the isolation insulating film near the light incident surface is less than a film thickness of a portion near the element formation surface.

### TECHNICAL FIELD

The present technology (technology according to the present disclosure) relates to a light detection device and an electronic apparatus, and more particularly to a light detection device and an electronic apparatus including miniaturized pixels.

### BACKGROUND ART

Recent imaging elements such as CMOS image sensors tend to have more pixels. To increase the number of pixels, it is necessary to further miniaturize the pixels. Then, increasing the depth dimension of miniaturized photodiodes suppresses a decrease in signal charge that can be accumulated in a single photodiode.

The increase in the depth dimension of photodiodes may hinder the transfer of the accumulated signal charge.

Patent Document 1 discloses that applying a potential repelling accumulated charge to a light-shielding film arranged in a grid pattern between pixels facilitates the transfer of accumulated electrons.

### CITATION LIST

Patent Document 1: Japanese Patent Application Laid-Open No. 2015-12126

### SUMMARY OF THE INVENTION

### Problems to be Solved by the Invention

Further miniaturization of pixels is anticipated, and transfer characteristics adapted to the miniaturization are required.

It is therefore an object of the present technology to provide a light detection device and an electronic apparatus capable of suppressing degradation of signal charge transfer characteristics.

### Solutions to Problems

A light detection device according to an aspect of the present technology includes: a semiconductor layer with one surface serving as an element formation surface and an other surface serving as a light incident surface, the semiconductor layer having a plurality of cell regions arranged in a matrix along row and column directions as viewed from above; a photoelectric conversion unit configured in each of the cell regions; and a trench isolation structure that extends along a thickness direction of the semiconductor layer and serves as a partition between the cell regions, in which the trench isolation structure includes a conductive wall including a conductive material, and an isolation insulating film that is provided on a side surface of the conductive wall and insulates the conductive wall from the semiconductor layer, and a film thickness of a portion of the isolation insulating film near the light incident surface is less than a film thickness of a portion near the element formation surface.

An electronic apparatus according to one aspect of the present technology includes the above light detection device, and an optical system that forms an image of image light from a subject on the light detection device.

### BRIEF DESCRIPTION OF DRAWINGS

FIG. 1 is a chip layout diagram illustrating a configuration example of a light detection device according to a first embodiment of the present technology.

FIG. 2 is a block diagram illustrating the configuration example of the light detection device according to the first embodiment of the present technology.

FIG. 3 is an equivalent circuit diagram of pixels of the light detection device according to the first embodiment of the present technology.

FIG. 4A is a longitudinal cross-sectional view illustrating a cross-sectional configuration of a pixel of the light detection device according to the first embodiment of the present technology.

FIG. 4B is an explanatory diagram illustrating a layout of a trench isolation structure on a second surface side of a semiconductor layer in the light detection device according to the first embodiment of the present technology.

FIG. 4C is an explanatory diagram illustrating a layout of a gate electrode on a first surface side of the semiconductor layer in the light detection device according to the first embodiment of the present technology.

FIG. 4D is a longitudinal cross-sectional view illustrating a cross-sectional configuration when the trench isolation structure is viewed in cross section along line B-B in FIG. 4B.

FIG. 5A is an explanatory diagram illustrating magnitude of potential in the semiconductor layer during charge accumulation with the position of the semiconductor layer in a Z direction on the horizontal axis.

FIG. 5B is an explanatory diagram illustrating magnitude of potential in the semiconductor layer during charge transfer with the position of the semiconductor layer in the Z direction on the horizontal axis.

FIG. 6A is a process cross-sectional view illustrating a method for manufacturing the light detection device according to the first embodiment of the present technology.

FIG. 6B is a process cross-sectional view subsequent to FIG. 6A.

FIG. 6C is a process cross-sectional view subsequent to FIG. 6B.

FIG. 6D is a process cross-sectional view subsequent to FIG. 6C.

FIG. 6E is a process cross-sectional view subsequent to FIG. 6D.

FIG. 6F is a process cross-sectional view subsequent to FIG. 6E.

FIG. 6G is a process cross-sectional view subsequent to FIG. 6F.

FIG. 7A is an explanatory diagram illustrating a cross-sectional configuration of a pixel and magnitude of potential of a semiconductor layer in a light detection device according to Comparative Example 1.

FIG. 7B is an explanatory diagram illustrating a cross-sectional configuration of a pixel and magnitude of potential of a semiconductor layer in a light detection device according to Comparative Example 2.

FIG. 7C is an explanatory diagram illustrating a cross-sectional configuration of a pixel and magnitude of potential of a semiconductor layer in a light detection device according to Comparative Example 3.

FIG. 8 is a longitudinal cross-sectional view illustrating a cross-sectional configuration when a trench isolation structure included in a light detection device according to Modification 1 of the first embodiment of the present technology is viewed in cross section.

FIG. 9 is a longitudinal cross-sectional view illustrating a cross-sectional configuration when a trench isolation structure included in a light detection device according to Modification 2 of the first embodiment of the present technology is viewed in cross section.

FIG. 10 is a longitudinal cross-sectional view illustrating a cross-sectional configuration when a trench isolation structure included in a light detection device according to Modification 3 of the first embodiment of the present technology is viewed in cross section.

FIG. 11A is a longitudinal cross-sectional view illustrating a cross-sectional configuration when a trench isolation structure included in a light detection device according to Modification 4 of the first embodiment of the present technology is viewed in cross section.

FIG. 11B is a longitudinal cross-sectional view illustrating a cross-sectional configuration when a trench isolation structure included in the light detection device according to Modification 4 of the first embodiment of the present technology is viewed in cross section.

FIG. 12 is a block diagram illustrating an example of a schematic configuration of an electronic apparatus.

### MODE FOR CARRYING OUT THE INVENTION

Hereinafter, preferred embodiments for carrying out the present technology will be described with reference to the drawings. Note that, the embodiments described hereinafter each illustrate an example of a representative embodiment of the present technology and should not be construed as limiting the scope of the present technology.

In the following drawings, the same or similar portions are denoted by the same or similar reference signs. It should be noted that the drawings are schematic, and a relationship between a thickness and a planar dimension, a ratio of thicknesses between layers, and the like are different from actual ones. Therefore, specific thicknesses and dimensions should be determined in consideration of the following description. Furthermore, it goes without saying that dimensional relationships and ratios are partly different between the drawings. Furthermore, since the drawings suitable for describing the present technology are adopted, there may be a difference in configuration between the drawings.

Furthermore, the embodiments described below illustrate devices and methods for embodying the technical idea of the present technology, and the technical idea of the present technology is not intended to limit the materials, shapes, structures, layouts, and the like of the components to those described below. Various changes can be made to the technical idea of the present technology within the technical scope defined by the claims.

Furthermore, definitions of directions such as up and down in the following description are merely definitions for convenience of description, and are not intended to limit the technical idea of the present disclosure. For example, it is a matter of course that when an object is observed by rotating the object by 90°, the up and down are converted into and read as left and right, and when the object is observed by rotating the object by 180°, the up and down are inverted and read.

The description will be given in the following order.
1. First embodiment
2. Application example for electronic apparatus

### First Embodiment

In this embodiment, an example in which the present technology is applied to a light detection device that is a back-illuminated complementary metal oxide semiconductor (CMOS) image sensor will be described.

### «Overall Configuration of Light Detection Device»

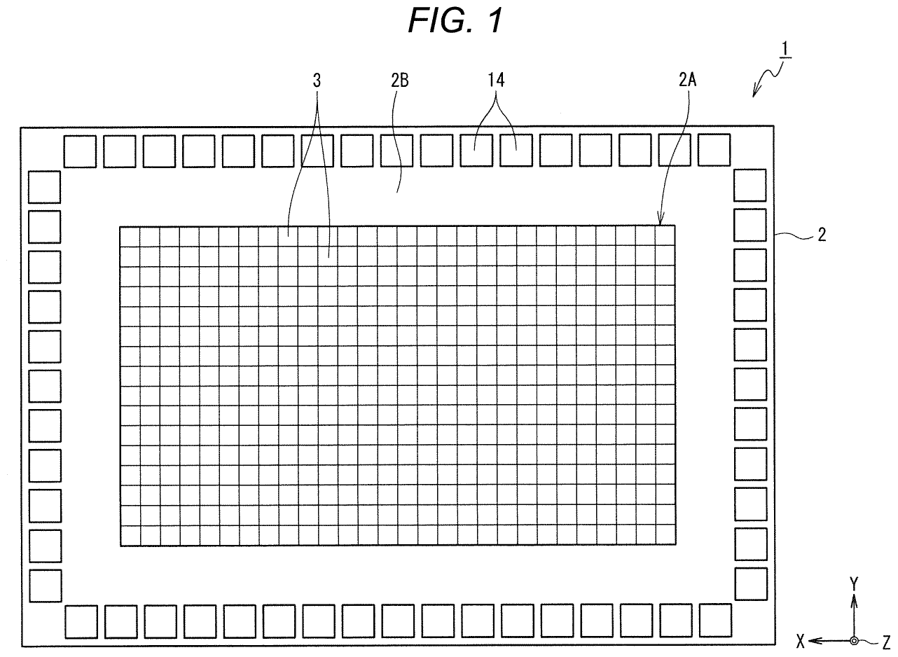

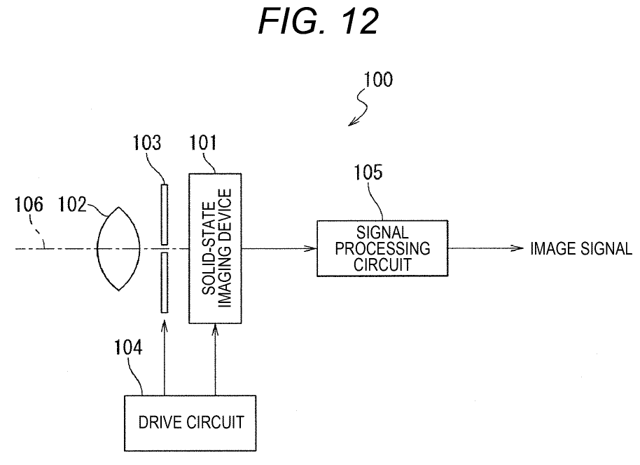

First, an overall configuration of a light detection device 1 will be described. As illustrated in FIG. 1, the light detection device 1 according to the first embodiment of the present technology is formed mainly with a semiconductor chip 2 having a rectangular two-dimensional planar shape as viewed from above. That is, the light detection device 1 is mounted on the semiconductor chip 2. As illustrated in FIG. 12, the light detection device 1 captures image light (incident light 106) from a subject via an optical system (optical lens) 102, converts the amount of the incident light 106 formed as an image on the imaging surface into an electrical signal pixel by pixel, and outputs the electrical signal as a pixel signal.

As illustrated in FIG. 1, the semiconductor chip 2 on which the light detection device 1 is mounted includes, in a two-dimensional plane including X and Y directions intersecting each other, a rectangular pixel region 2A provided in a central portion, and a peripheral region 2B provided outside the pixel region 2A to surround the pixel region 2A.

The pixel region 2A is a light receiving surface that receives light collected by the optical system 102 illustrated in FIG. 12, for example. Then, in the pixel region 2A, a plurality of pixels 3 is arranged in a matrix in the two-dimensional plane including the X and Y directions. In other words, the pixels 3 are repeatedly arranged in each of the X and Y directions intersecting each other in the two-dimensional plane. Note that, in the present embodiment, the X and Y directions are orthogonal to each other, for example. Furthermore, a direction orthogonal to both the X and Y directions is a Z direction (thickness direction, stacking direction). Furthermore, a direction perpendicular to the Z direction is a horizontal direction.

As illustrated in FIG. 1, a plurality of bonding pads 14 is arranged in the peripheral region 2B. Each of the plurality of bonding pads 14 is arranged along each of the four sides of the semiconductor chip 2 in the two-dimensional plane, for example.

Each of the plurality of bonding pads 14 is an input/output terminal that is used for electrically connecting the semiconductor chip 2 to an external device.

### <Logic Circuit>

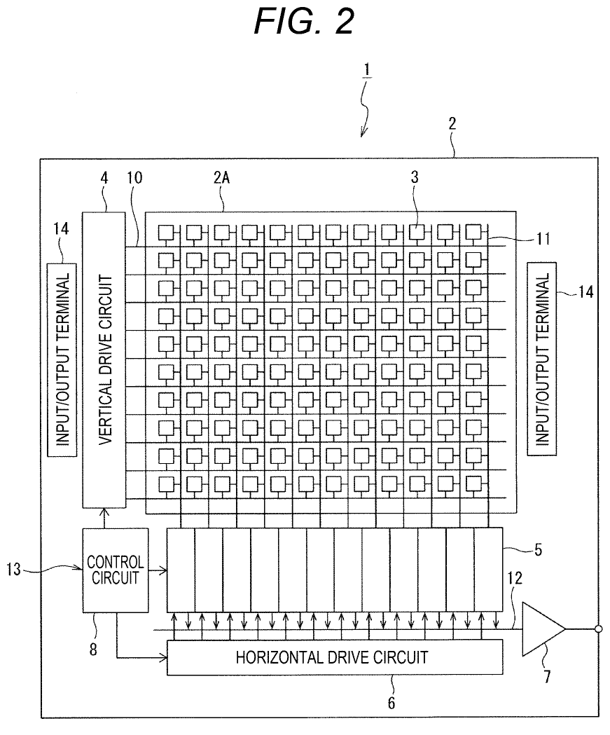

As illustrated in FIG. 2, the semiconductor chip 2 includes a logic circuit 13. The logic circuit 13 includes a vertical drive circuit 4, a column signal processing circuit 5, a horizontal drive circuit 6, an output circuit 7, a control circuit 8, and the like. The logic circuit 13 includes a complementary MOS (CMOS) circuit including an n-channel metal oxide semiconductor field effect transistor (MOSFET) and a p-channel MOSFET as field effect transistors, for example.

The vertical drive circuit 4 includes a shift register, for example. The vertical drive circuit 4 sequentially selects a desired pixel drive line 10 and supplies a pulse for driving the pixels 3 to the selected pixel drive line 10 to drive each pixel 3 on a row-by-row basis. That is, the vertical drive circuit 4 selects and scans each of the pixels 3 in the pixel region 2A sequentially in the vertical direction on a row-by-row basis, and supplies a pixel signal from each of the pixels 3 based on signal charge generated by a photoelectric conversion element of the pixel 3 in accordance with the amount of received light to the column signal processing circuit 5 through a vertical signal line 11.

The column signal processing circuit 5 is, for example, arranged for each column of the pixels 3 and performs signal processing such as noise removal on signals output from one row of the pixels 3 for each pixel column. For example, the column signal processing circuit 5 performs signal processing such as correlated double sampling (CDS) for removing pixel-specific fixed pattern noise, and analog-to-digital (AD) conversion. A horizontal selection switch (not illustrated) is arranged in the output stage of the column signal processing circuit 5, and is connected to a horizontal signal line 12.

The horizontal drive circuit 6 includes a shift register, for example. The horizontal drive circuit 6 sequentially selects each column signal processing circuit 5 by sequentially outputting a horizontal scanning pulse to the column signal processing circuit 5, and causes each column signal processing circuit 5 to output a pixel signal subjected to the signal processing to the horizontal signal line 12.

The output circuit 7 performs signal processing on the pixel signal sequentially supplied from each column signal processing circuit 5 through the horizontal signal line 12, and outputs a processed signal. As the signal processing, buffering, black level adjustment, column variation correction, various kinds of digital signal processing, and the like can be used, for example.

The control circuit 8 generates a clock signal and a control signal that serves as references for operation of the vertical drive circuit 4, the column signal processing circuit 5, the horizontal drive circuit 6, and the like on the basis of a vertical synchronization signal, a horizontal synchronization signal, and a master clock signal. Then, the control circuit 8 outputs the generated clock signal and control signal to the vertical drive circuit 4, the column signal processing circuit 5, the horizontal drive circuit 6, and the like.

### <Pixel>

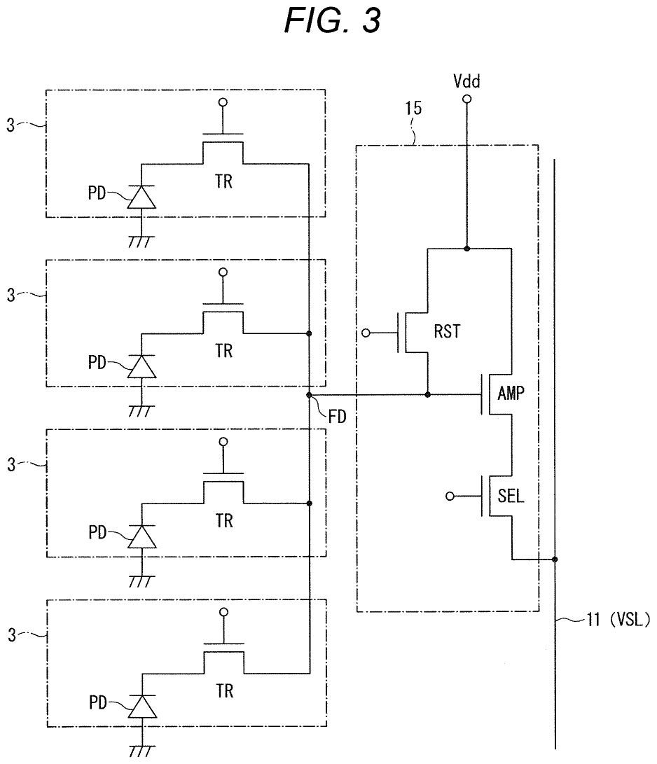

FIG. 3 is an equivalent circuit diagram illustrating a configuration example of the pixel 3. In the illustrated example, a plurality of the pixels 3 shares a charge accumulation region (floating diffusion) FD and a readout circuit 15. More specifically, four pixels 3 share a single charge accumulation region (floating diffusion) FD and a single readout circuit 15. Each pixel 3 includes a photoelectric conversion element PD, and a transfer transistor TR that transfers signal charge generated by photoelectric conversion in the photoelectric conversion element PD to the charge accumulation region FD. The readout circuit 15 is connected to the subsequent stage of the charge accumulation region FD.

The photoelectric conversion element PD generates signal charge corresponding to the amount of received light.

Furthermore, the photoelectric conversion element PD temporarily accumulates (holds) the generated signal charge. The photoelectric conversion element PD has a cathode side electrically connected to a source region of the transfer transistor TR, and an anode side electrically connected to a reference potential line (for example, ground). As the photoelectric conversion element PD, for example, a photodiode is used.

The transfer transistor TR has a drain region electrically connected to the charge accumulation region FD. The transfer transistor TR has a gate electrode electrically connected to a transfer transistor drive line among the pixel drive lines 10 (see FIG. 2).

The charge accumulation region FD temporarily accumulates and holds the signal charge transferred from the photoelectric conversion element PD via the transfer transistor TR.

The readout circuit 15 reads the signal charge accumulated in the charge accumulation region FD, and outputs a pixel signal based on the signal charge. The readout circuit 15 includes, but is not limited to, an amplification transistor AMP, a selection transistor SEL, and a reset transistor RST as pixel transistors, for example. Each of these transistors (AMP, SEL, and RST) includes a MOSFET including a gate insulating film formed with a silicon oxide film (SiO₂ film), a gate electrode, and a pair of main electrode regions functioning as a source region and a drain region, for example. Furthermore, each of these transistors may be a metal insulator semiconductor FET (MISFET) whose gate insulating film is a silicon nitride film (Si₃N₄ film) or a multilayer film including a silicon nitride film and a silicon oxide film.

The amplification transistor AMP has a source region electrically connected to a drain region of the selection transistor SEL, and a drain region electrically connected to a power supply line Vdd and a drain region of the reset transistor. Then, the amplification transistor AMP has a gate electrode electrically connected to the charge accumulation region FD and a source region of the reset transistor RST.

The selection transistor SEL has a source region electrically connected to the vertical signal line 11 (VSL), and the drain electrically connected to the source region of the amplification transistor AMP. Then, the selection transistor SEL has a gate electrode electrically connected to a selection transistor drive line among the pixel drive lines 10 (see FIG. 2).

The reset transistor RST has the source region electrically connected to the charge accumulation region FD and the gate electrode of the amplification transistor AMP, and the drain region electrically connected to the power supply line Vdd and the drain region of the amplification transistor AMP. The reset transistor RST has a gate electrode electrically connected to a reset transistor drive line among the pixel drive lines 10 (see FIG. 2).

«Specific configuration of light detection device»

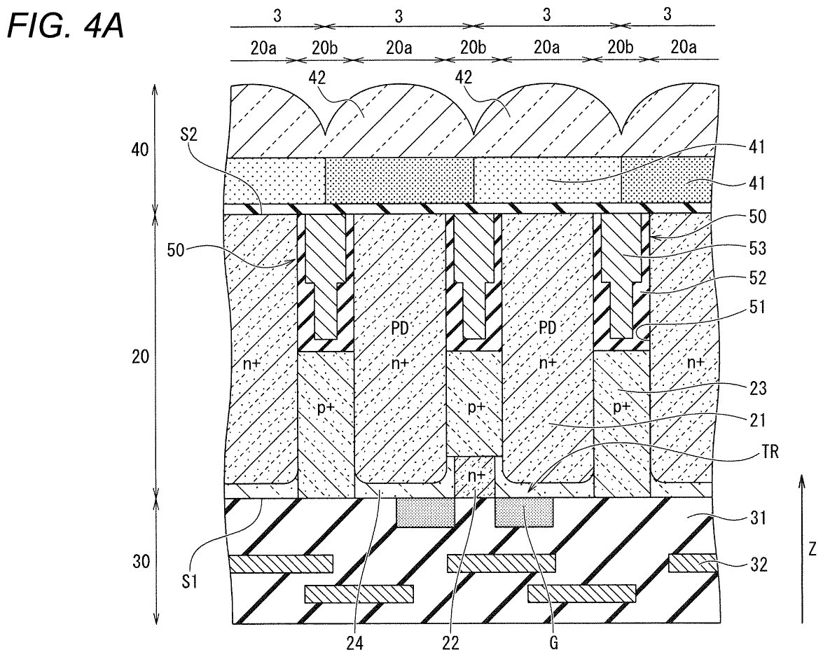

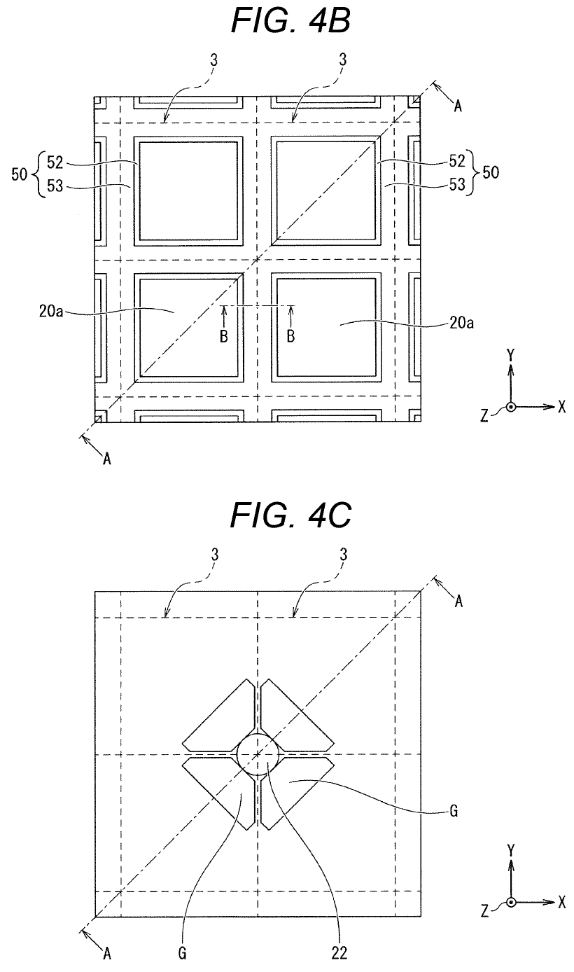

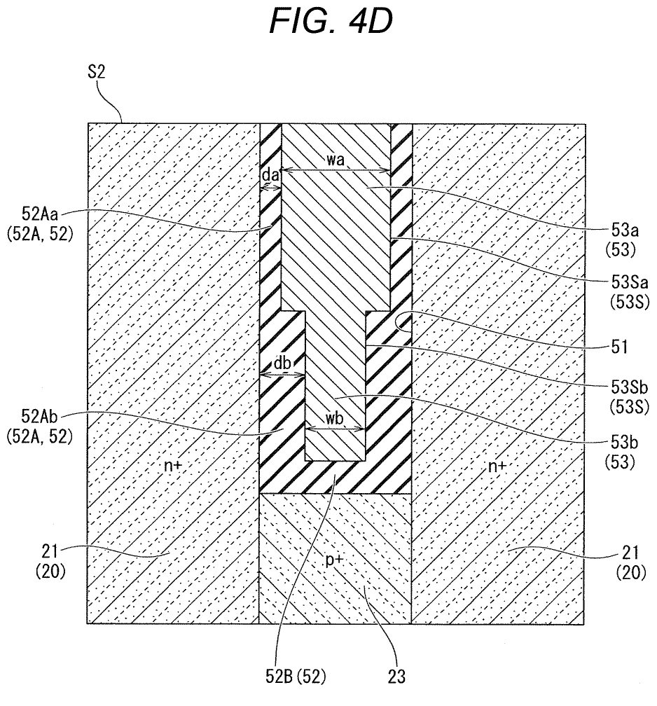

Next, a specific configuration of the light detection device 1 will be described with reference to FIGS. 4A to 4D.

Note that illustrations of a barrier metal layer, a transistor gate insulating film, and the like may be omitted.

### <Multilayer Structure of Light Detection Device>

FIG. 4A is a longitudinal cross-sectional view illustrating a cross-sectional configuration when viewed in cross section along line A-A in FIGS. 4B and 4C. As illustrated in FIG. 4A, the light detection device 1 (semiconductor chip 2) includes, for example, a semiconductor layer 20 with one surface referred to as a first surface S1 and the other surface referred to as a second surface S2. A wiring layer 30 is laminated on the first surface S1 side of the semiconductor layer 20, and a light-incident side multilayer body 40 is laminated on the second surface S2 side. That is, the light detection device 1 has a multilayer structure of the light-incident side multilayer body 40, the semiconductor layer 20, and the wiring layer 30.

### <Semiconductor Layer>

The semiconductor layer 20 includes a semiconductor substrate. The semiconductor layer 20 includes, but is not limited thereto, a single-crystal silicon (Si) substrate, for example. Note that the first surface S1 may be referred to as an element formation surface or a principal surface, and the second surface S2 may be referred to as a light incident surface or a back surface. A portion corresponding to the pixel region 2A of the semiconductor layer 20 is provided with a plurality of cell regions 20a arranged in a matrix along row and column directions as viewed from above. The cell regions 20a are provided on a one-to-one basis for each pixel 3. For example, the island-shaped cell regions 20a partitioned by isolation regions 20b are provided on a one-to-one basis for each pixel 3. Note that the number of pixels 3 is not limited to that illustrated in FIG. 4A.

In the semiconductor layer 20, a photoelectric conversion unit 21 that is a semiconductor region of a second conductivity type (for example, n+ type), a charge accumulation region 22 that is a semiconductor region of the second conductivity type (for example, n+ type), a well region 24 that is a semiconductor region of a first conductivity type (for example, p type), and the transfer transistor TR are configured. Then, the photoelectric conversion element PD, the transfer transistor TR, and the charge accumulation region FD illustrated in FIG. 3 are configured in the semiconductor layer 20. The photoelectric conversion unit 21 serves as a photoelectric conversion region configured in each cell region 20a. The concentration of impurities contained in the photoelectric conversion unit 21 is not intentionally varied along the Z direction. For example, in a case where impurity ion implantation is performed in multiple steps to form the photoelectric conversion unit 21, the ion implantation is performed so as to minimize concentration differences along the Z direction. The impurity concentration of the photoelectric conversion unit 21 formed as described above can be considered uniform along the Z direction. In the present embodiment, the impurities implanted into the photoelectric conversion unit 21 are known impurities that impart the second conductivity type (for example, n+ type) to the photoelectric conversion unit 21. Then, the photoelectric conversion element PD illustrated in FIG. 3 is configured in each cell region 20a. The charge accumulation region 22 is shared by a plurality of pixels 3 (four pixels 3 in the present embodiment), and is configured in, for example, the isolation region 20b, but is not limited to such a configuration. Note that at least a part of the charge accumulation region 22 may be configured in the cell region 20a. The transfer transistor TR includes the photoelectric conversion unit 21 functioning as a source region, the charge accumulation region 22 functioning as a drain region, the well region 24 functioning as a channel formation region, and a gate electrode G and a gate insulating film (not illustrated) provided in the wiring layer 30. Note that FIG. 4A and the subsequent drawings illustrate examples of the shape and extent of the well region 24. The shape and extent of the well region 24 are not limited to those illustrated in FIG. 4A, but may be other forms. As illustrated in FIG. 4C, the gate electrodes G of the four pixels 3 arranged in two rows and two columns are arranged at the respective corners of the pixels 3 so as to surround the charge accumulation region 22.

Returning to FIG. 4A, the description will be continued.

The transfer transistor TR interrupts an electrical connection between the photoelectric conversion unit 21 and the charge accumulation region 22 in response to the voltage applied to the gate electrode G. Furthermore, the transfer transistor TR forms a channel in the well region 24 in response to the voltage applied to the gate electrode G to establish the electrical connection between the photoelectric conversion unit 21 and the charge accumulation region 22. During charge accumulation in which signal charge is accumulated in the photoelectric conversion unit 21, a potential repelling the signal charge is applied to the gate electrode G to interrupt the electrical connection between the photoelectric conversion unit 21 and the charge accumulation region 22. During charge transfer in which signal charge is transferred from the photoelectric conversion unit 21 to the charge accumulation region 22, a potential attracting the signal charge is applied to the gate electrode G to form a channel between the photoelectric conversion unit 21 and the charge accumulation region 22. In the present embodiment, it is assumed that the signal charge is an electron, a negative potential is applied to the gate electrode G during charge accumulation to raise the potential between the photoelectric conversion unit 21 and the charge accumulation region 22, and a positive potential is applied to the gate electrode G during charge transfer to lower the potential between the photoelectric conversion unit 21 and the charge accumulation region 22, for example. Furthermore, the description will be given on the assumption that the transfer transistor TR is in the OFF state in a case where the negative potential is applied to the gate electrode G, and the transfer transistor TR is in the ON state in a case where the positive potential is applied to the gate electrode G.

The isolation region 20b is provided with an isolation structure that serves as a partition between the cell regions 20a. More specifically, in the isolation region 20b, as the isolation structure, a trench isolation structure 50 and a semiconductor region 23 of the first conductivity type (for example, p type) are provided in this order from the second surface S2 side along the Z direction. That is, the trench isolation structure 50 is located near the second surface S2 rather than the first surface S1, and is located away from the transfer transistor TR along the Z direction compared to the semiconductor region 23. Hereinafter, the trench isolation structure 50 will be described in more detail.

### <Trench Isolation Structure>

In addition to the function as the above-described isolation structure, the trench isolation structure 50 has a function as a light-shielding portion that blocks stray light between the pixels 3, and a transfer promotion function that facilitates the flow of signal charge toward the first surface S1 during charge transfer. FIG. 4D is a longitudinal cross-sectional view illustrating a cross-sectional configuration when the trench isolation structure 50 is viewed in cross section along line B-B in FIG. 4B. The trench isolation structure 50 includes a conductive wall 53 including a conductive material, and an isolation insulating film 52 including an insulating material that is provided between the conductive wall 53 and the semiconductor layer 20 and insulates the conductive wall 53 from the semiconductor layer 20. Then, the trench isolation structure 50 has a trench isolation structure in which the conductive wall 53 and the isolation insulating film 52 are embedded in a trench groove 51 formed from the second surface S2 side. A first potential or a second potential is applied to the conductive wall 53 via a signal line (not illustrated) under the control of the control circuit 8 (FIG. 2). More specifically, during charge accumulation, 0 V (zero potential) is applied to the conductive wall 53 as the first potential. During charge transfer, a potential repelling the signal charge is applied to the conductive wall 53 as the second potential. In the present embodiment, the signal charge is an electron, and during charge transfer, a negative potential is applied to the conductive wall 53 as the second potential.

The isolation insulating film 52 includes an isolation insulating film 52A that is a portion provided on a side surface 53S of the conductive wall 53, and an isolation insulating film 52B that is a portion provided on a bottom surface of the conductive wall 53. Unless otherwise distinguished, the isolation insulating film 52A and the isolation insulating film 52B are simply referred to as the isolation insulating film 52.

The insulating material of the isolation insulating film 52 may be a known insulating material. Examples of the insulating material include silicon oxide (SiO₂), silicon nitride (Si₃N₄), and an organic material. Furthermore, the insulating material is desirably a material that can be easily embedded in the trench groove 51. The conductive wall 53, being used as an electrode, includes a conductive material. The conductive material of the conductive wall 53 may be a known conductive material. Examples of the conductive material include semiconductor materials such as polysilicon, and metal materials such as aluminum (Al) and tungsten (W).

FIG. 4B is an explanatory diagram illustrating a layout of the trench isolation structure 50 on the second surface S2 side of the semiconductor layer 20. The trench isolation structure 50 has a portion extending along the Z and X directions and a portion extending along the Z and Y directions. Similarly, the isolation insulating film 52 and the conductive wall 53 each have a portion extending along the Z and X directions and a portion extending along the Z and Y directions. A longitudinal cross-sectional structure of the trench isolation structure 50 is the same between the portion extending along the Z and X directions and the portion extending along the Z and Y directions. One end of the trench isolation structure 50 along the Z direction is flush with the second surface S2 and has a grid shape surrounding the cell region 20a at a position near the second surface S2 along the Z direction. Furthermore, as illustrated in FIG. 4A, the other end of the trench isolation structure 50 along the Z direction does not reach the first surface S1.

Although FIG. 4D illustrates only the second surface S2, out of the first surface S1 and the second surface S2, of the semiconductor layer 20, the first surface S1 of the semiconductor layer 20 is located opposite the second surface S2. As illustrated in FIG. 4D, a thickness wa of a portion of the conductive wall 53 near the second surface S2 is greater than a thickness wb of a portion near the first surface S1 (wb<wa). More specifically, the thickness of the conductive wall 53 varies in a gradual, stepwise manner from the first surface S1 side to the second surface S2 side. In the present embodiment, the conductive wall 53 has a two-step configuration of a conductive wall 53b that is the portion near the first surface S1 and a conductive wall 53a that is a portion near the second surface S2, and the thickness wa of the conductive wall 53a is greater than the thickness wb of the conductive wall 53b.

A film thickness da of a portion of the isolation insulating film 52A near the second surface S2 is less than a film thickness db of a portion near the first surface S1 (da<db). More specifically, the thickness of the isolation insulating film 52A varies in a gradual, stepwise manner (stepped manner) from the first surface S1 side to the second surface S2 side. In the present embodiment, the isolation insulating film 52A has a two-step configuration of an isolation insulating film 52Ab that is a portion near the first surface S1 and an isolation insulating film 52Aa that is a portion near the second surface S2, and the film thickness da of the isolation insulating film 52Aa is less than the film thickness db of the isolation insulating film 52Ab. Note that the isolation insulating film 52Aa is a portion that is in contact with a side surface 53Sa of the conductive wall 53a, and the isolation insulating film 52Ab is a portion that is in contact with a side surface 53Sb of the conductive wall 53b.

### <Wiring Layer>

As illustrated in FIG. 4A, the wiring layer 30 is, for example, a multilayer wiring layer including an insulating film 31 and wiring 32 provided in the insulating film 31, but is not limited to such a configuration. The wiring 32 includes vertical wiring extending mainly in the thickness direction and horizontal wiring extending mainly in the horizontal direction, and serves as, for example, at least a part of the wiring portion of the circuit illustrated in FIG. 3. The insulating film 31 has a multilayer configuration in which a plurality of known insulating films such as a silicon oxide (SiO₂) film, a silicon nitride (Si₃N₄) film, and a silicon oxynitride (SiON) film is laminated together. The wiring 32 includes a known conductive material such as a semiconductor material such as polysilicon, or a metal material such as copper (Cu), tungsten (W), or aluminum (Al).

### <Light-incident Side Multilayer Body>

The light-incident side multilayer body 40 includes, for example, a color filter 41 and a microlens 42 in this order from the semiconductor layer 20. The microlens 42 is an on-chip lens, and concentrates incident light onto the semiconductor layer 20. The color filter 41 separates the incident light after passing through the microlens 42 into color components. The color filter 41 and the microlens 42 are provided for each pixel 3, for example. The color filter 41 and the microlens 42 include, for example, a resin material.

### «Function»

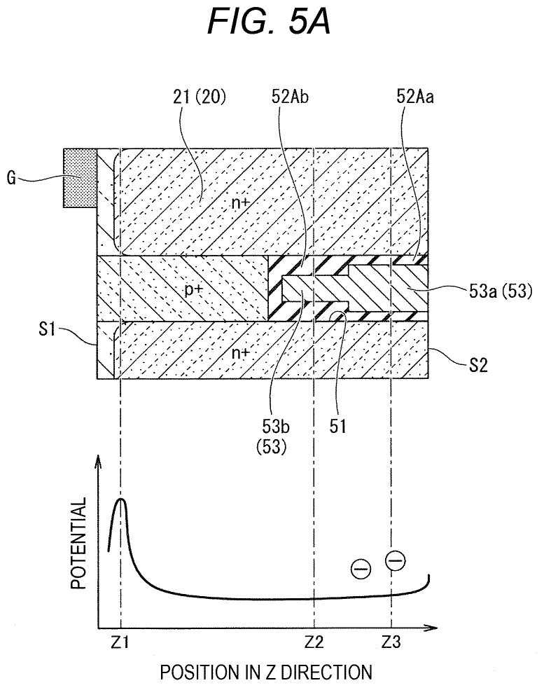

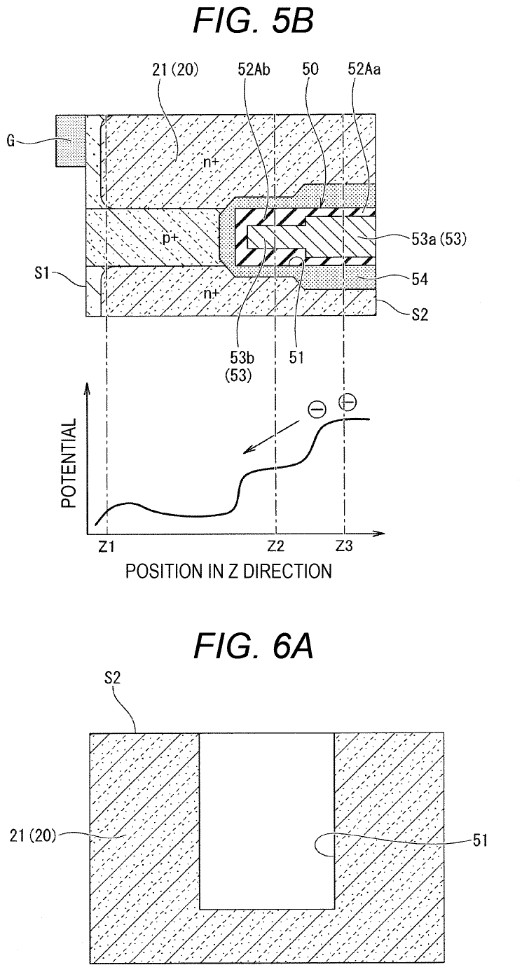

Hereinafter, the function of the light detection device 1 according to the first embodiment of the present technology will be described with reference to FIGS. 5A and 5B. FIG. 5A illustrates magnitude of potential in the semiconductor layer 20 during charge accumulation with the position of the semiconductor layer 20 in the Z direction as the horizontal axis, and FIG. 5B illustrates magnitude of potential in the semiconductor layer 20 during charge transfer with the position of the semiconductor layer 20 in the Z direction as the horizontal axis. A position Z1 along the Z direction shown on the horizontal axis is a position near the first surface S1 and in the vicinity of the transfer transistor TR. A position Z2 along the Z direction shown on the horizontal axis is a position where the isolation insulating film 52Ab is located. A position Z3 along the Z direction shown on the horizontal axis is a position where the isolation insulating film 52Aa is located and near the second surface S2.

In FIG. 5A, since the transfer transistor TR is in the OFF state during charge accumulation, the potential at the position Z1 increases, and signal charge generated in accordance with the amount of received light is accumulated in the photoelectric conversion unit 21. Furthermore, during charge accumulation, 0 V is applied to the conductive wall 53 as the first potential. The potential is maintained at a low level along the Z direction, except near the position Z1. More specifically, the potential at each of the positions Z2 and Z3 is maintained at a low level.

This enables the photoelectric conversion unit 21 to suppress a decrease in the accumulated signal charge even at a position that is away from the transfer transistor TR and near the second surface S2 along the Z direction.

In FIG. 5B, the transfer transistor TR is in the ON state during charge transfer. Therefore, the potential at the position Z1 decreases, and the generated signal charge is transferred from the photoelectric conversion unit 21 to the charge accumulation region 22. Furthermore, during charge transfer, a negative potential is applied to the conductive wall 53 as the second potential. Upon application of the negative potential to the conductive wall 53, a depletion layer 54 is formed in the semiconductor layer 20 around the trench isolation structure 50, and the potential at the positions Z2 and Z3 increases. More specifically, the potential at the position Z3 becomes higher than the potential at the position Z2, and the potential decreases in a stepped manner from the position Z3 toward the position Z1. More specifically, a portion of the depletion layer 54 formed around the thin isolation insulating film 52Aa is greater in thickness along the horizontal direction than a portion formed around the thick isolation insulating film 52Ab.

This makes the potential at the position 23 higher than the potential at the position Z2. Therefore, the signal charge accumulated at the position near the second surface S2 of the photoelectric conversion unit 21, that is, the position away from the transfer transistor TR can easily flow from the position Z3 toward the position Z1 along the stepped potential.

### «Method for Manufacturing Light Detection Device»

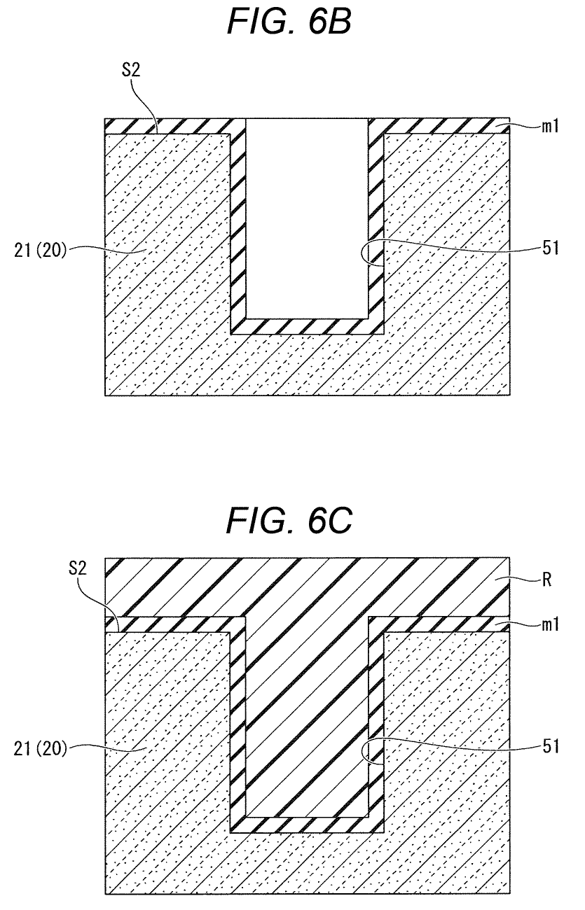

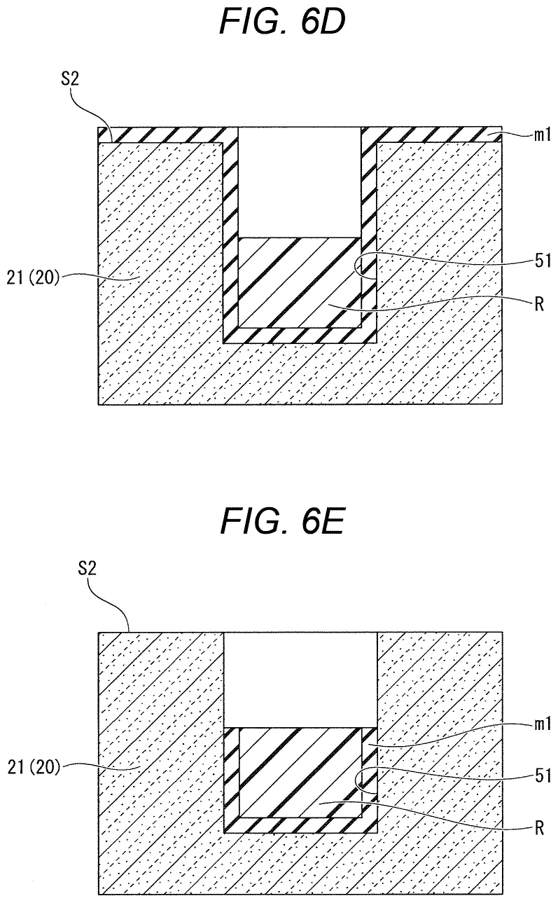

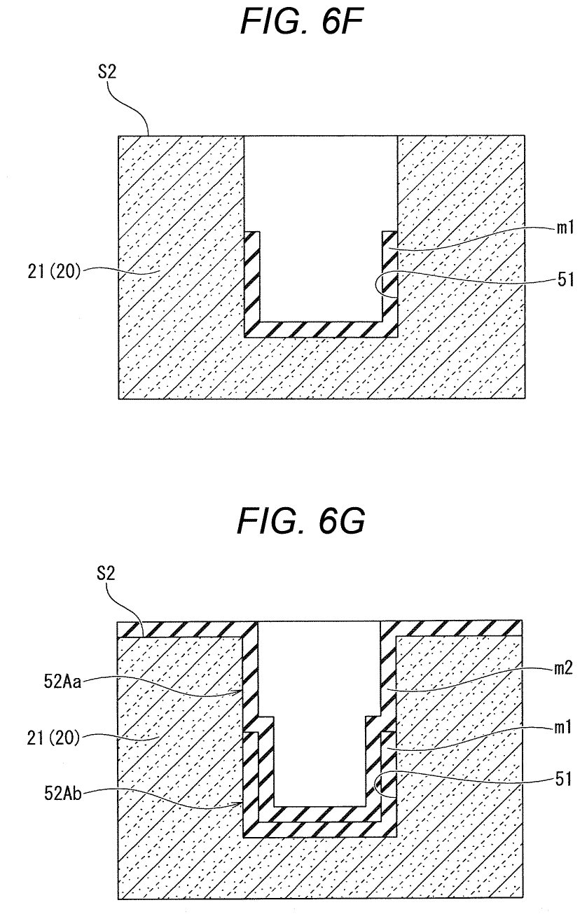

Hereinafter, a method for manufacturing the light detection device 1 will be described with reference to FIGS. 6A to 6G.

Note that, in the present embodiment, a method for forming the trench isolation structure 50 will be mainly described, and description of the other portions will be omitted. Furthermore, in FIGS. 6A to 6G, the semiconductor region 23 (FIG. 4A) is not illustrated.

First, as illustrated in FIG. 6A, the trench groove 51 is formed in the semiconductor layer 20 from the second surface S2 side using a known etching technique. Then, as illustrated in FIG. 6B, an insulating film ml is formed so as to cover the inner surface of the trench groove 51. The insulating film ml includes the same material as the isolation insulating film 52. Thereafter, as illustrated in FIG. 6C, a resist R is applied so as to fill the trench groove 51. Then, as illustrated in FIG. 6D, etch-back is performed to remove a part of the resist embedded in the trench groove 51.

Next, as illustrated in FIG. 6E, an excess portion of the insulating film m1 is removed using hydrofluoric acid. More specifically, a portion of the insulating film m1 that is not covered with the resist R is removed. As a result of this process, the insulating film m1 remains on the lower portion of the trench groove 51 in the drawing. Thereafter, as illustrated in FIG. 6F, the resist R is removed. Thereafter, as illustrated in FIG. 6G, an insulating film m2 is formed so as to cover the inner surface of the trench groove 51 and the exposed surface of the insulating film m1. The insulating film m2 includes the same material as the isolation insulating film 52. This enables the isolation insulating film 52Aa and the isolation insulating film 52Ab to be formed along the sidewall of the trench groove 51.

Next, although not illustrated, a conductive material constituting the conductive wall 53 is embedded so as to fill the remaining space in the trench groove 51, and an excess portion of the conductive material is removed to form the conductive wall 53. An excess portion of the insulating film m2 is also removed. The subsequent manufacturing method may be performed by a known method, and thus its description will be omitted.

### «Main Effect of First Embodiment»

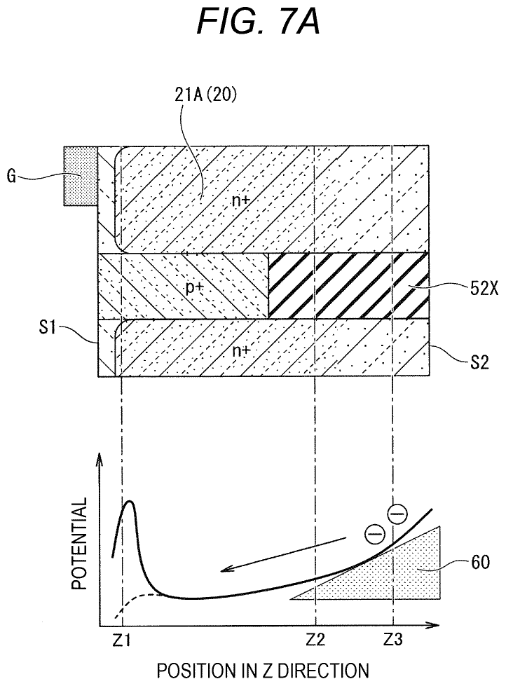

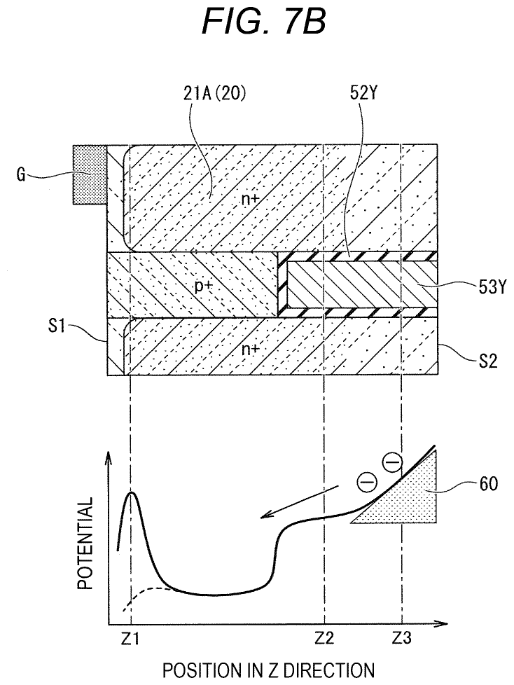

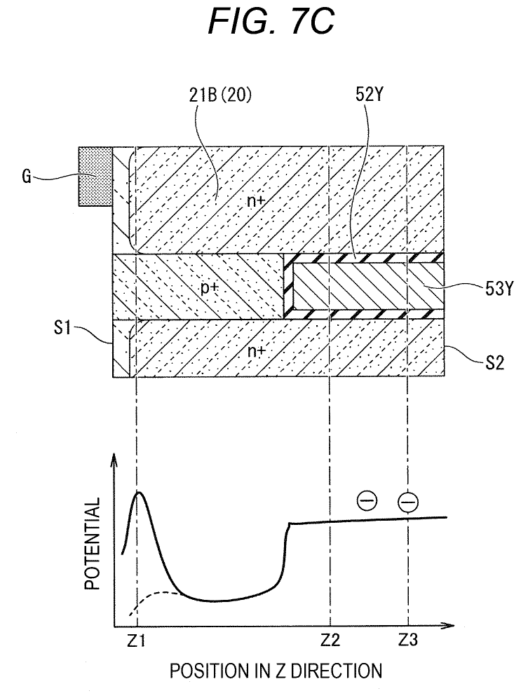

Hereinafter, a main effect of the first embodiment will be described, but before that, an overview of the present technology and comparative examples illustrated in FIGS. 7A, 7B, and 7C will be described. Recent light detection devices tend to have more pixels, and in order to arrange more pixels, the pixels 3 have been miniaturized. In order to incorporate a large number of pixels 3 into a single light detection device, it is necessary to reduce the planar dimensions of the pixels 3.

Furthermore, there is also a demand for obtaining bright images even in dark environments. In order to obtain bright images, it is necessary to suppress a decrease in the amount of signal charge that can be accumulated in the photoelectric conversion unit. However, when the pixels 3 are miniaturized, the dimensions of the pixels 3 become smaller, and there is a possibility that the number of saturated electrons that can be accumulated in the photoelectric conversion unit decreases.

Therefore, there is a demand for increasing the dimension of the photoelectric conversion unit along the thickness direction of the semiconductor layer 20 in order to suppress a decrease in the number of saturated electrons. However, in a case where the dimension of the photoelectric conversion unit along the thickness direction of the semiconductor layer 20 is increased, when signal charge generated near the light incident surface of the photoelectric conversion unit is transferred toward the element formation surface where the transfer transistor is provided, the travel distance becomes longer. Therefore, in order to improve the signal charge transfer characteristics, technology according to the following comparative examples has been conceived.

A light detection device according to Comparative Example 1 illustrated in FIG. 7A is provided with an insulating layer 52X instead of the trench isolation structure 50. Furthermore, the concentration of impurities contained in a photoelectric conversion unit 21A is set lower in the portion near the second surface S2 than in the other portion. More specifically, when the photoelectric conversion unit 21A is formed by performing impurity ion implantation in multiple steps, the impurity concentration of the portion near the second surface S2 is intentionally decreased by changing the dose of impurities or the like in accordance with the depth position in the Z direction. As described above, by changing the impurity concentration of the photoelectric conversion unit 21A along the Z direction, the potential gradually increases from the position 22 toward the position Z3, which facilitates the flow of signal charge during charge transfer. However, in a case where the impurity concentration of the photoelectric conversion unit 21A is changed, the state in which the potential gradually increases from the position 22 toward the position Z3 is maintained even during charge accumulation. This makes it difficult to accumulate signal charge in the region indicated by a reference numeral 60, and there is a possibility that the number of saturated electrons decreases.

A light detection device according to Comparative Example 2 illustrated in FIG. 7B is provided with a conductive wall 53Y via an insulating layer 52Y, instead of the insulating layer 52X. The insulating layer 52Y has a uniform film thickness. The other portions have the same configuration as the light detection device according to Comparative Example 1. As described above, by providing the conductive wall 53Y, the potential can be further increased from the position 22 to the position Z3, which further facilitates the flow of signal charge during charge transfer. However, since the impurity concentration of the photoelectric conversion unit 21A is changed as in Comparative Example 1, it is difficult to accumulate signal charge in the region indicated by the reference numeral 60 during charge accumulation, and there is a possibility that the number of saturated electrons decreases.

In a light detection device according to Comparative Example 3 illustrated in FIG. 7C, the concentration of impurities contained in a photoelectric conversion unit 21B is not intentionally varied, and can be considered uniform along the Z direction. The other portions have the same configuration as the light detection device according to Comparative Example 2. As described above, making the concentration of impurities contained in the photoelectric conversion unit 21B uniform eliminates the region of potential indicated by the reference numeral 60; accordingly, more charge can be accumulated during charge accumulation, and a decrease in the number of saturated electrons can be suppressed, compared to Comparative Examples 1 and 2. However, in a case where a negative potential is applied to the conductive wall 53Y during charge transfer, the potential on the second surface S2 side becomes generally higher, but no gradient is formed, thereby making it difficult for signal charge to flow easily.

On the other hand, in the light detection device 1 according to the first embodiment of the present technology, the film thickness of the portion of the isolation insulating film 52 near the light incident surface is less than the film thickness of the portion near the element formation surface. Therefore, by applying a negative potential to the conductive wall 53 during charge transfer, the potential of the semiconductor layer 20 becomes higher in the portion near the light incident surface than in the portion near the element formation surface. This forms a potential difference between the portion near the light incident surface and the portion near the element formation surface; accordingly, signal charge easily flows toward the element formation surface, allowing suppression of degradation of transfer characteristics. More specifically, even in a case where the dimension of the photoelectric conversion unit 21 in the thickness direction of the semiconductor layer 20 is increased, signal charge easily flows toward the element formation surface, allowing suppression of degradation of transfer characteristics. Furthermore, by applying a zero potential to the conductive wall 53 during charge accumulation, it is possible to suppress an increase in potential on the light incident surface side, and more specifically, it is possible to make the potential on the light incident surface side nearly flat. It is therefore possible to suppress a decrease in the number of saturated electrons during charge accumulation. This allows suppression of degradation of images captured in dark environments.

Furthermore, in the light detection device 1 according to the first embodiment of the present technology, the thickness of the isolation insulating film 52 varies in a gradual, stepwise manner from the element formation surface side to the light incident surface side. Therefore, by applying a negative potential to the conductive wall 53 during charge transfer, the potential of the semiconductor layer 20 decreases in a gradual, stepwise manner from the portion near the light incident surface toward the portion near the element formation surface.

Accordingly, signal charge easily flows toward the element formation surface, allowing suppression of the degradation of transfer characteristics.

Furthermore, in the light detection device 1 according to the first embodiment of the present technology, the trench isolation structure 50 is provided at least in the portion of the semiconductor layer 20 near the light incident surface.

Therefore, by applying a negative potential to the conductive wall 53 during charge transfer, signal charge accumulated at a position away from the transfer transistor TR easily flows toward the element formation surface, allowing suppression of degradation of transfer characteristics. More specifically, even in a case where the dimension of the photoelectric conversion unit 21 in the thickness direction of the semiconductor layer 20 is increased, signal charge accumulated at a position away from the transfer transistor TR easily flows toward the element formation surface, allowing suppression of degradation of transfer characteristics.

Furthermore, in the light detection device 1 according to the first embodiment of the present technology, the concentration of impurities contained in the photoelectric conversion unit 21 is uniform along the thickness direction of the semiconductor layer 20. Therefore, during charge accumulation, it is possible to suppress an increase in the potential on the light incident surface side, and more specifically, it is possible to make the potential on the light incident surface side nearly flat. It is therefore possible to suppress a decrease in the number of saturated electrons during charge accumulation. This allows suppression of degradation of images captured in dark environments.

### «Modifications of First Embodiment»

Hereinafter, modifications of the first embodiment will be described.

### <Modification 1>

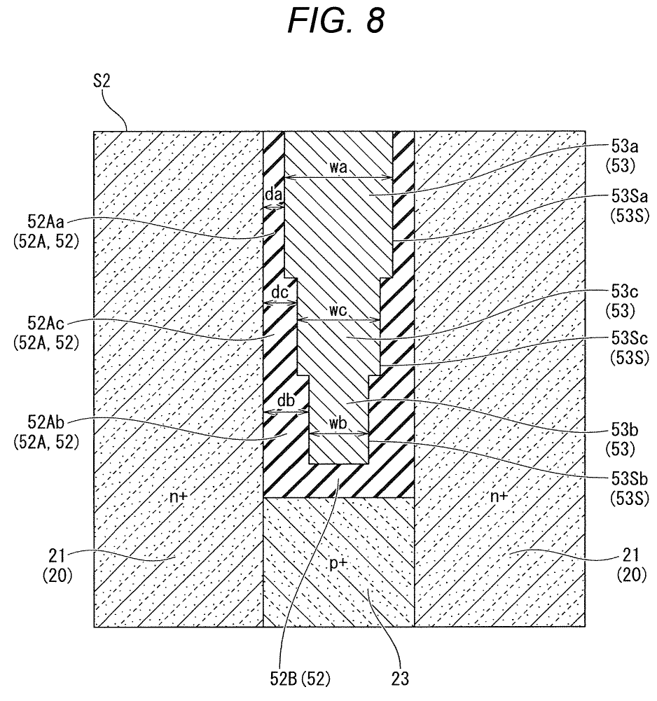

In the light detection device 1 according to the first embodiment, as illustrated in FIG. 4D, the isolation insulating film 52A has a two-step configuration of the isolation insulating film 52Ab that is a portion near the first surface S1 and the isolation insulating film 52Aa that is a portion near the second surface S2, but the present technology is not limited to such a configuration. In a light detection device 1 according to Modification 1 of the first embodiment, as illustrated in FIG. 8, the isolation insulating film 52A has a three-step configuration of an isolation insulating film 52Ab that is a portion near the first surface S1, an isolation insulating film 52Aa that is a portion near the second surface S2, and an isolation insulating film 52Ac located between the isolation insulating film 52Ab and the isolation insulating film 52Aa.

A film thickness da of the isolation insulating film 52Aa is less than a film thickness dc of the isolation insulating film 52Ac, and the film thickness dc of the isolation insulating film 52Ac is less than a film thickness db of the isolation insulating film 52Ab (da<dc<db). As described above, the thickness of the isolation insulating film 52A varies in a gradual, stepwise manner (stepped manner) from the first surface S1 side to the second surface S2 side. Furthermore, the conductive wall 53 has a three-step configuration of a conductive wall 53b that is a portion near the first surface S1, a conductive wall 53a that is a portion near the second surface S2, and a conductive wall 53c located between the conductive wall 53b and the conductive wall 53a. Then, a thickness wa of the conductive wall 53a is greater than a thickness wc of the conductive wall 53c, and the thickness wc of the conductive wall 53c is greater than a thickness wb of the conductive wall 53b (wb <wc <wa). Then, the isolation insulating film 52Ac is a portion that is in contact with a side surface 53Sc of the conductive wall 53c. Note that the isolation insulating film 52A and the conductive wall 53 described above each have a three-step configuration, but may have a configuration having four or more steps.

Effects similar to those of the light detection device 1 according to the first embodiment described above can also be achieved with the light detection device 1 according to Modification 1 of the first embodiment.

### <Modification 2>

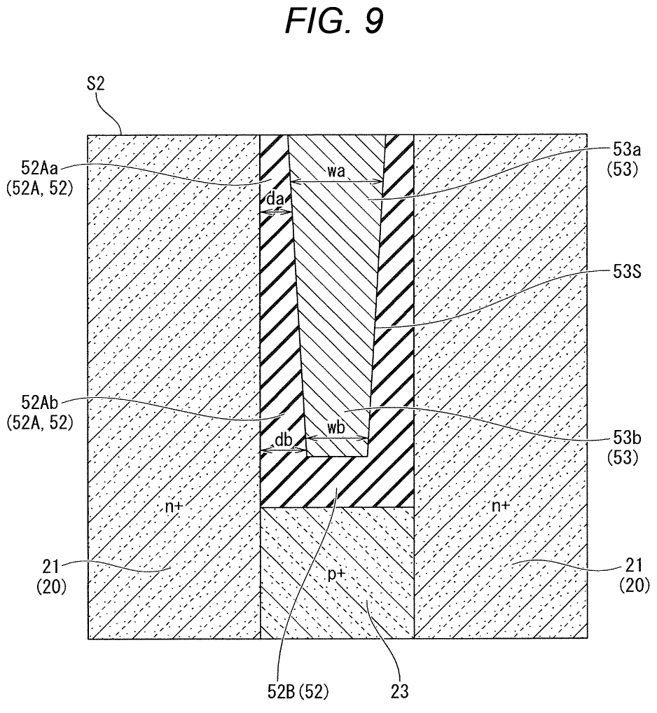

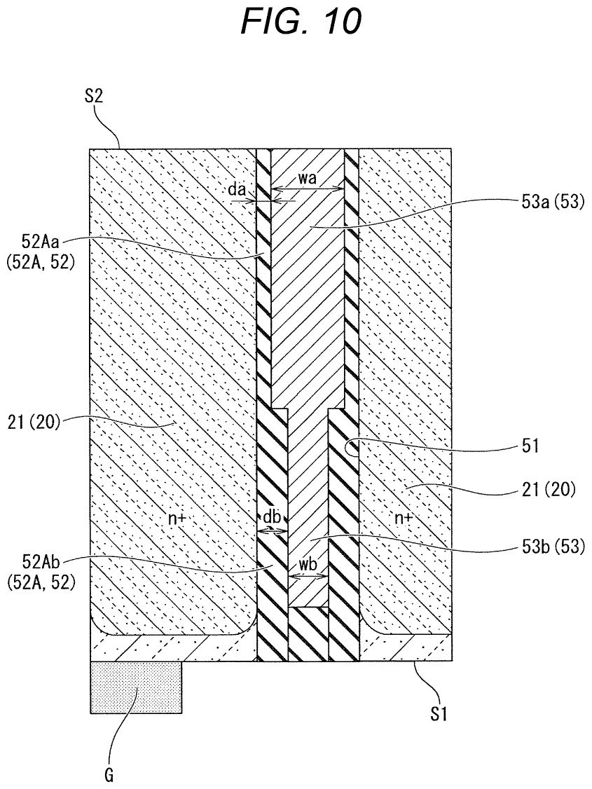

In the light detection device 1 according to the first embodiment, as illustrated in FIG. 4D, the thickness of the isolation insulating film 52A decreases in a gradual, stepwise manner from the first surface S1 side to the second surface S2 side, but the present technology is not limited to such a configuration. In a light detection device 1 according to Modification 2 of the first embodiment, as illustrated in FIG. 9, the thickness of the isolation insulating film 52A decreases in a gradual, continuous manner from the first surface S1 side to the second surface S2 side. Furthermore, in the light detection device 1 according to the first embodiment, as illustrated in FIG. 4D, the thickness of the conductive wall 53 increases in a gradual, stepwise manner from the first surface S1 side to the second surface S2 side, but the present technology is not limited to such a configuration. In the light detection device 1 according to Modification 2 of the first embodiment, as illustrated in FIG. 9, the thickness of the conductive wall 53 increases in a gradual, continuous manner from the first surface S1 side to the second surface S2 side.

Effects similar to those of the light detection device 1 according to the first embodiment described above can also be achieved with the light detection device 1 according to Modification 2 of the first embodiment.

### <Modification 3>

In the light detection device 1 according to the first embodiment, as illustrated in FIG. 4A, the trench groove 51 is provided from the second surface S2 side, and the trench isolation structure 50 and the semiconductor region 23 of the first conductivity type are provided in this order from the second surface S2 side along the Z direction as the isolation structure, but the present technology is not limited to such a configuration. A light detection device 1 according to Modification 3 of the first embodiment has a configuration where the trench groove 51 is provided from the first surface S1 side, and the semiconductor region 23 is not provided, as illustrated in FIG. 10. This allows the trench isolation structure 50 to be provided to extend from the first surface S1 to the second surface S2.

Effects similar to those of the light detection device 1 according to the first embodiment described above can also be achieved with the light detection device 1 according to Modification 3 of the first embodiment.

### <Modification 4>

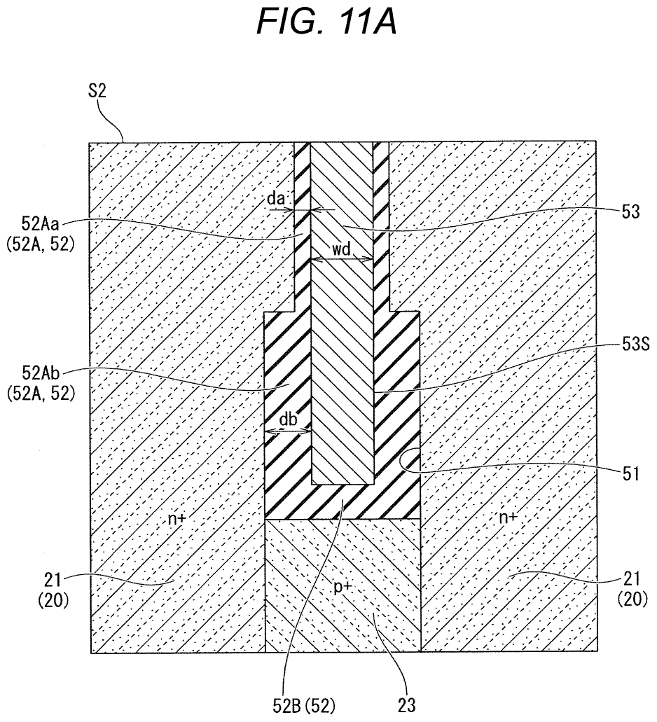

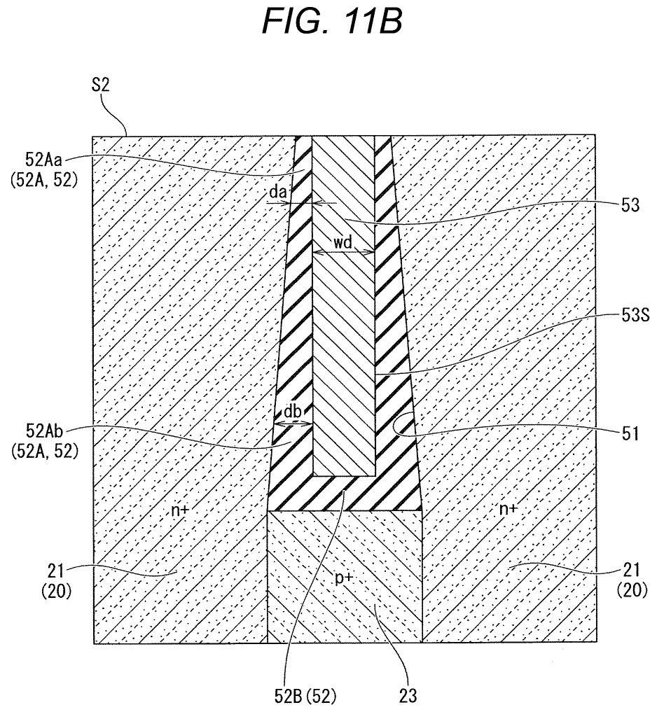

In the light detection device 1 according to the first embodiment, as illustrated in FIG. 4D, the thickness of the conductive wall 53 increases in a gradual, stepwise manner from the first surface S1 side to the second surface S2 side, but the present technology is not limited to such a configuration. In a light detection device 1 according to Modification 4 of the first embodiment, a thickness wd of the conductive wall 53 is substantially uniform along the thickness direction of the semiconductor layer 20, as illustrated in FIGS. 11A and 11B. In the present modification, to make the film thickness of the portion of the isolation insulating film 52 near the second surface S2 less than the film thickness of the portion near the first surface S1, the width of the trench groove 51 is varied along the thickness direction of the semiconductor layer 20. As illustrated in FIG. 11A, the width of the trench groove 51 is decreased in a gradual, stepwise manner from the first surface S1 to the second surface S2. Furthermore, as illustrated in FIG. 11B, the width of the trench groove 51 is decreased in a gradual, continuous manner from the first surface S1 to the second surface S2.

Effects similar to those of the light detection device 1 according to the first embodiment described above can also be achieved with the light detection device 1 according to Modification 4 of the first embodiment.

### «Application Example for Electronic Apparatus»

Next, an electronic apparatus 100 illustrated in FIG. 12 will be described. The electronic apparatus 100 includes a solid-state imaging device 101, an optical lens 102, a shutter device 103, a drive circuit 104, and a signal processing circuit 105. The electronic apparatus 100 is, for example, an electronic apparatus such as a camera, but is not limited thereto. Furthermore, the electronic apparatus 100 includes the light detection device 1 described above as the solid-state imaging device 101.

The optical lens (optical system) 102 forms an image of image light (incident light 106) from the subject on the imaging surface of the solid-state imaging device 101. Therefore, signal charge is accumulated in the solid-state imaging device 101 over a certain period of time. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. In accordance with the drive signal (timing signal) supplied from the drive circuit 104, the solid-state imaging device 101 performs signal transfer. The signal processing circuit 105 performs various kinds of signal processing on the signal (pixel signal) output from the solid-state imaging device 101. An image signal subjected to the signal processing is stored into a storage medium such as a memory or output to a monitor.

With such a configuration, since the solid-state imaging device 101 of the electronic apparatus 100 includes the above-described pixels 3, it is possible to improve the image quality of the image signal.

Note that the electronic apparatus 100 is not limited to a camera and may be any other electronic apparatus. For example, the electronic apparatus may be an imaging device such as a camera module for a mobile device such as a mobile phone.

Furthermore, the electronic apparatus 100 may include, as the solid-state imaging device 101, the light detection device 1 according to any one of the first embodiment and the modifications thereof, or the light detection device 1 according to a combination of at least two of the first embodiment and the modifications thereof.

### [Other Embodiments]

While the present technology has been described with reference to the above embodiment and modifications thereof, it should not be understood that the description and drawings constituting a part of this disclosure limit the present technology. Various alternative embodiments, examples, and operation techniques will be apparent to those skilled in the art from this disclosure.

For example, the respective technical ideas described in the above embodiment and modifications thereof can be combined with each other. Various combinations can be made in accordance with the respective technical ideas.

Furthermore, the present technology is applicable to any light detection devices including not only the above-described solid-state imaging device as an image sensor but also a ranging sensor also called a time of flight (ToF) sensor that measures distances, and the like. The ranging sensor is a sensor that emits irradiation light toward an object, detects reflected light that is the irradiation light reflected off a surface of the object, and calculates a distance to the object on the basis of a flight time from the emission of the irradiation light to the reception of the reflected light. As a structure of the ranging sensor, the structure of the pixel 3 described above may be adopted.

Furthermore, the light detection device 1 may be a stacked CMOS image sensor (CIS) in which two or more semiconductor substrates are stacked on top of each other. In that case, elements included in at least one of the logic circuit 13 or the readout circuit 15 may be provided on a substrate different from the semiconductor substrate on which the cell regions 20a are provided among these semiconductor substrates.

Furthermore, the longitudinal cross-sectional configurations of the modifications illustrated in FIGS. 8 to 11B correspond to cross-sectional configurations when the trench isolation structure is viewed in cross section along line B-B in FIG. 4B used for the description of the first embodiment.

Furthermore, the materials mentioned as constituting the components described above may contain additives, impurities, or the like, for example.

As described above, it goes without saying that the present technology includes various embodiments and the like not described herein. Therefore, the technical scope of the present technology is defined solely by the matters specifying the invention recited in the claims that are reasonably derived from the above description.

Furthermore, the effects described herein are merely examples and are not intended to be limiting, and other effects may also be achieved.

Note that the present technology may have the following configurations.

(1)

A light detection device including:
a semiconductor layer with one surface serving as an element formation surface and an other surface serving as a light incident surface, the semiconductor layer having a plurality of cell regions arranged in a matrix along row and column directions as viewed from above;
a photoelectric conversion unit configured in each of the cell regions; and
a trench isolation structure that extends along a thickness direction of the semiconductor layer and serves as a partition between the cell regions, in which
the trench isolation structure includes a conductive wall including a conductive material, and an isolation insulating film that is provided on a side surface of the conductive wall and insulates the conductive wall from the semiconductor layer, and
a film thickness of a portion of the isolation insulating film near the light incident surface is less than a film thickness of a portion near the element formation surface.
   (2)

The light detection device according to (1), in which a thickness of the isolation insulating film varies in a gradual, stepwise manner from the element formation surface side to the light incident surface side.

(3)

The light detection device according to (1), in which a thickness of the isolation insulating film varies in a gradual, continuous manner from the element formation surface side to the light incident surface side.

(4)

The light detection device according to any one of (1) to (3), in which a thickness of a portion of the conductive wall near the light incident surface is greater than a thickness of a portion near the element formation surface.

(5)

The light detection device according to (4), in which the thickness of the conductive wall varies in a gradual, stepwise manner from the element formation surface side to the light incident surface side.

(6)

The light detection device according to (4), in which the thickness of the conductive wall varies in a gradual, continuous manner from the element formation surface side to the light incident surface side.

(7)

The light detection device according to any one of (1) to (6), in which the trench isolation structure is provided in at least a portion of the semiconductor layer near the light incident surface.

(8)

The light detection device according to any one of (1) to (7), in which a concentration of impurities contained in the photoelectric conversion unit is uniform along the thickness direction of the semiconductor layer.

(9)

The light detection device according to any one of (1) to (8), further including:
a control circuit;
a charge accumulation region configured in the semiconductor layer; and
a transfer transistor that transfers signal charge generated in the photoelectric conversion unit to the charge accumulation region, in which
the control circuit performs control to apply a potential repelling the signal charge to the conductive wall only during charge transfer in which the signal charge generated in the photoelectric conversion unit is transferred to the charge accumulation region rather than during charge accumulation in which the signal charge generated in the photoelectric conversion unit is accumulated.
   (10)

The light detection device according to (9), in which the control circuit performs control to apply a zero potential to the conductive wall during the charge accumulation.

(11)

An electronic apparatus including:
a light detection device and an optical system that forms an image of image light from a subject on the light detection device, in which
the light detection device includes:
a semiconductor layer with one surface serving as an element formation surface and an other surface serving as a light incident surface, the semiconductor layer having a plurality of cell regions arranged in a matrix along row and column directions as viewed from above;
a photoelectric conversion unit configured in each of the cell regions; and
a trench isolation structure that extends along a thickness direction of the semiconductor layer and serves as a partition between the cell regions,
the trench isolation structure includes a conductive wall including a conductive material, and an isolation insulating film that is provided on a side surface of the conductive wall and insulates the conductive wall from the semiconductor layer, and
a film thickness of a portion of the isolation insulating film near the light incident surface is less than a film thickness of a portion near the element formation surface.

The scope of the present technology is not limited to the illustrated and described exemplary embodiments, but also includes all embodiments that produce effects equivalent to those intended by the present technology. Moreover, the scope of the present technology is not limited to the combinations of the features of the invention defined by the claims, and may be defined by any desired combination of specific features among all the disclosed features.

### REFERENCE SIGNS LIST

1 Light detection device
3 Pixel
8 Control circuit
15 Readout circuit
20 Semiconductor layer
20a Cell region
21 Photoelectric conversion unit
22 Charge accumulation region
50 Trench isolation structure
52, 52A, 52Aa, 52Ab, 52Ac, 52B Isolation insulating film
53, 53a, 53b, 53c Conductive wall
53S, 53Sa, 53Sb, 53Sc Side surface
100 Electronic apparatus
102 Optical system
da, db, dc Film thickness
FD Charge accumulation region
m1, m2 Insulating film
TR Transfer transistor

1. A light detection device comprising:
a semiconductor layer with one surface serving as an element formation surface and an other surface serving as a light incident surface, the semiconductor layer having a plurality of cell regions arranged in a matrix along row and column directions as viewed from above;
a photoelectric conversion unit configured in each of the cell regions; and
a trench isolation structure that extends along a thickness direction of the semiconductor layer and serves as a partition between the cell regions, wherein
the trench isolation structure includes a conductive wall including a conductive material, and an isolation insulating film that is provided on a side surface of the conductive wall and insulates the conductive wall from the semiconductor layer, and
a film thickness of a portion of the isolation insulating film near the light incident surface is less than a film thickness of a portion near the element formation surface.

2. The light detection device according to claim 1, wherein a thickness of the isolation insulating film varies in a gradual, stepwise manner from the element formation surface side to the light incident surface side.

3. The light detection device according to claim 1, wherein a thickness of the isolation insulating film varies in a gradual, continuous manner from the element formation surface side to the light incident surface side.

4. The light detection device according to claim 1, wherein a thickness of a portion of the conductive wall near the light incident surface is greater than a thickness of a portion near the element formation surface.

5. The light detection device according to claim 4, wherein the thickness of the conductive wall varies in a gradual, stepwise manner from the element formation surface side to the light incident surface side.

6. The light detection device according to claim 4, wherein the thickness of the conductive wall varies in a gradual, continuous manner from the element formation surface side to the light incident surface side.

7. The light detection device according to claim 1, wherein the trench isolation structure is provided in at least a portion of the semiconductor layer near the light incident surface.

8. The light detection device according to claim 1, wherein a concentration of impurities contained in the photoelectric conversion unit is uniform along the thickness direction of the semiconductor layer.

9. The light detection device according to claim 1, further comprising:
a control circuit;
a charge accumulation region configured in the semiconductor layer; and
a transfer transistor that transfers signal charge generated in the photoelectric conversion unit to the charge accumulation region, wherein
the control circuit performs control to apply a potential repelling the signal charge to the conductive wall only during charge transfer in which the signal charge generated in the photoelectric conversion unit is transferred to the charge accumulation region rather than during charge accumulation in which the signal charge generated in the photoelectric conversion unit is accumulated.

10. The light detection device according to claim 9, wherein the control circuit performs control to apply a zero potential to the conductive wall during the charge accumulation.

11. An electronic apparatus comprising:
a light detection device and an optical system that forms an image of image light from a subject on the light detection device, wherein
the light detection device includes:
a semiconductor layer with one surface serving as an element formation surface and an other surface serving as a light incident surface, the semiconductor layer having a plurality of cell regions arranged in a matrix along row and column directions as viewed from above;
a photoelectric conversion unit configured in each of the cell regions; and
a trench isolation structure that extends along a thickness direction of the semiconductor layer and serves as a partition between the cell regions,
the trench isolation structure includes a conductive wall including a conductive material, and an isolation insulating film that is provided on a side surface of the conductive wall and insulates the conductive wall from the semiconductor layer, and
a film thickness of a portion of the isolation insulating film near the light incident surface is less than a film thickness of a portion near the element formation surface.
